(19) United States
(12) Patent Application Publication
(10) Pub. No.: US 2005/0077620 A1
(43) Pub. Date: Apr. 14, 2005

(54) Miniaturized small memory card structure

(76) Inventor: Chung Hsien Hsin, Hsinchu Hsien (TW)

Correspondence Address: PRO-TECHTOR INTERNATIONAL, 20775 Norada Court, Saratoga, CA, 95070-3018, US

(21) Appl. No.: 10/683,835

(22) Filed: Oct. 9, 2003

(51) Int. Cl. H01L 23/34

(52) U.S. Cl. 257/723

(57) ABSTRACT

A miniaturized small memory card includes a substrate, at least one upper memory chip, at least the lower memory chip, one upper glue layer, and one lower glue layer, the substrate is formed with an upper surface and a lower surface, the upper surface is formed with a plurality of connected points, the lower surface is formed with a frame to cause a cavity, which formed a plurality of connected points, formed between the frame and the substrate, the frame is formed with a plurality of golden fingers, the golden fingers are electrically connected to an electric device, the upper memory chip, which is mounted on the upper surface of the substrate, electrically connected to the plurality of connected points of the upper surface, the lower memory chip, which is mounted on the cavity of the lower surface of the substrate, electrically connected to a plurality of connected points of the lower surface, the upper glue layer encapsulated the upper surface of the substrate, so that at least one upper memory chip will be packaged, the lower glue layer encapsulated the lower surface of the substrate, so that at least one lower memory chip will be packaged.

### BACKGROUND OF THE INVENTION

1. Field of the Invention

The present invention relates to a refined-structure small memory card, and more particular to a small memory card with decreased volume.

2. Description of the Related Art

The prior method for producing a general memory card always packs chips to single integrated circuits, then mounts the IC onto a printed circuit board by the way of surface mount technique (SMT). The chip may be a memory element, such as flash memory. The golden fingers mounted on the printed circuit board for inserting into a slot of a computer main-board. In addition to some passive elements such as resistance, capacitor and inductor are mounted on the memory card.

Referring to FIG. 1 showing the side schematic illustrates of a prior memory card, the golden finger 15 is used to insert into a slot of a computer main-board, there are active elements and passive elements on the module card, the active elements usually are packed to an integrated circuit 11. Each integrated circuit 11 encapsulates a chip 12, which may be a memory chip, for example a flash memory chip. The pins 13 of integrated circuit 11 are mounted on the printed circuit board 14 of the memory card by SMT, the printed circuit board 14 has solder points 17 connected to pins 13. The prior arts has the following disadvantages:

1. A chip 12 must be packed then mounted on the circuit board 14, so more steps is unnecessary leads to the cost in manufacturing and packing will be increased.

2. A memory card always includes many ICs so that the integrated circuit 11 must be mounted on the PCB 14 one by one during manufacturing the module card.

3. The cost of SMT is expensive. Special manufacture devices such as a SMT machine and a solder furnace will extra the cost of equipment.

4. The chip 12 of a small memory card is packed in conventional manner, so that the volume of a small memory card may not be reduced advantageously.

### SUMMARY OF THE INVENTION

The object of the present invention is to provide a refined-structure small memory card may be manufactured conveniently, the manufacturing processes may be simplified and the manufacturing cost may decrease.

To achieve the above-mentioned object, the present invention includes a substrate, at least one upper memory chip, at least one lower memory chip, an upper glue layer and a lower glue layer. The substrate has an upper surface and a lower surface, the upper surface formed with a plurality of connected points, the lower surface arranged a frame, so the cavity formed between the frame and the substrate, and the cavity arranged a plurality of connected points, the frame formed with a plurality of golden fingers, which is used to electrically connect to the electric device, electrically connected a plurality of connected points, the upper memory chip that is arranged on the upper surface of the substrate electrically connected to a plurality of connected points, the lower memory chip, which is arranged in the cavity on the lower surface of the substrate, electrically connected to a plurality of connected points on the lower surface, the upper glue layer is encapsulated the upper surface of the substrate to package each of the upper memory chips, and the lower glue layer is encapsulated the lower surface of the substrate to package each of the lower memory chips. Thus, the refined-structure small memory card may be manufactured conveniently, also the manufacturing processes may be simplified and the manufacturing cost may decrease.

According to one aspect of the present invention, the heat of the memory chip may be traveled via the disperse heat slice. Therefore, proving the durability and dependability of small memory card.

### BRIEF DESCRIPTION OF THE DRAWINGS

FIG. 1 is a schematic illustrates showing a conventional small memory card structure.

FIG. 2 is a cross-sectional view illustrates showing a refined-structure small memory card of the present invention.

FIG. 3 is another cross-sectional view illustrates showing the small memory card structure of the present invention.

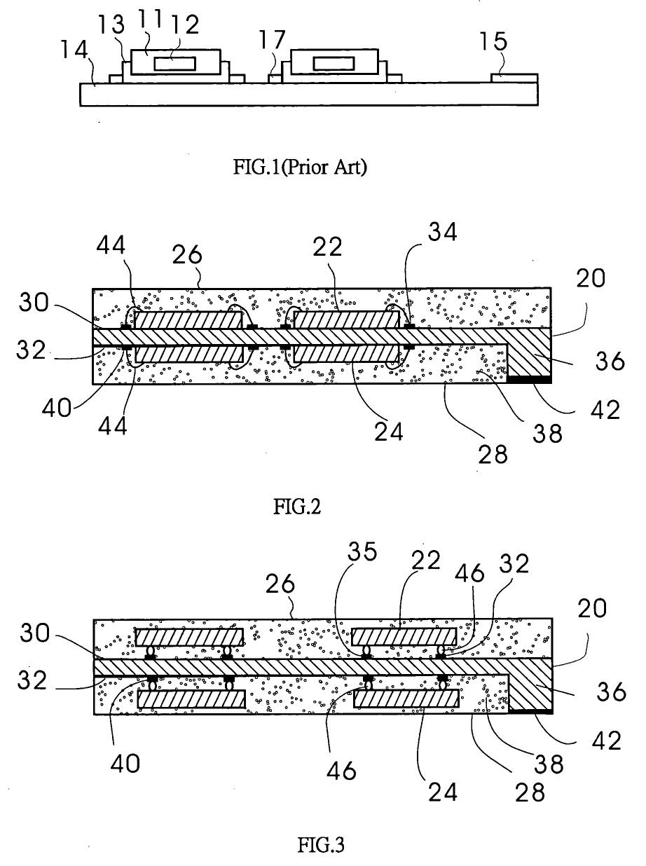

### DETAILED DESCRIPTION OF THE INVENTION

FIG. 2 is showing a cross-sectional view of a refined-structure small memory card of the present invention, which included a substrate 20, two upper memory chips 22, two lower memory chips 24, an upper glue layer 26 and a lower glue layer 28.

The substrate 20 is formed with an upper surface 30 and a lower surface 32, the upper surface 30 is formed with a plurality of connected points 34, the lower surface 32 is formed with a frame 36 to cause a cavity 38 arranged a plurality of connected points 40, the frame 36 is formed with a plurality of golden fingers 42 electrically connecting to a plurality of connected points 40, the golden fingers 42 is used to electrically connect to an electric device.

Two upper memory chips 22, which are arranged on the upper surface 30 of the substrate 20, electrically connected to a plurality of connected points 34 of the upper surface 30 of the substrate 20 via a plurality of wires 44.

Two lower memory chips 24, which are arranged in the cavity 38 on the lower surface 32 of the substrate 20, electrically connected to a plurality of connected points 40 of the lower surface 32 of the substrate 20 via a plurality of wires 44.

An upper glue layer 26 is encapsulated the upper surface 30 of the substrate to make two upper memory chips 22 be packaged.

A lower glue layer 28 is encapsulated the lower surface 32 of the substrate to make two lower memory chips 24 be packaged.

Referring to FIG. 3, in the embodiment, the upper memory chip 22 is electrically connected to the connected points 34 of the upper surface 30 of the substrate 20 via the golden ball 46 by way of coating manner, the lower memory chip 24 is electrically connected to the connected points 40 of the lower surface 32 of the substrate 20 via golden ball 46 by way of coating manner, the upper glue layer 26 is encapsulated the upper surface 30 of the substrate 20 to make two upper memory chips 22 be packaged at the same time, the lower memory chip 28 is encapsulated the lower surface 32 of the substrate 20 to make two lower memory chips 24 be packaged.

Therefore, the small memory card of the present invention has the following advantages.

1. Since the upper memory chip 22 and lower memory chip 24 are arranged on the substrate 20 then use the upper glue layer 26 and lower glue layer 28 respectively to package both the upper memory chip 22 and lower memory chip 24, so as to the manufacturing processes may be simplified and the manufacturing cost may decreased.

2. Since the golden fingers 42 are formed under the framed 36, and the upper memory chip 24 is arranged in the cavity 38, as to the memory card may be packaged into smooth rectangle, so that the memory card may be conveniently inserted into slot.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

1. A miniaturized small memory card to be set in an electric device, comprising:
A substrate having an upper surface and a lower surface, the upper surface formed with a plurality of connected points, the lower surface formed with a frame to cause a cavity formed between the frame and the substrate, the cavity also formed with a plurality of connected points, which electrically connected to a plurality of golden fingers of the frame, and the golden fingers are used to electrically connect to the electric device;
At least one upper memory chip, which formed on the upper surface of the substrate, electrically connected to a plurality of connected points of the upper surface;
At least one lower memory chip, which formed in the cavity on the lower surface of the substrate, electrically connected to a plurality of connected points of the lower surface;
An upper glue layer being encapsulated the upper surface of the substrate to cover at least one upper memory chip; and
A lower glue layer being encapsulated the lower surface of the substrate to cover at least one lower memory chip.

2. The miniaturized small memory card according to claim 1, wherein the upper memory chips are electrically connected to the connected points of the upper surface of the substrate via a plurality of wires.

3. The miniaturized small memory card according to claim 1, wherein the lower memory chip is electrically connected to the connected points of the upper surface of the substrate via a plurality of wires.

4. The miniaturized small memory card according to claim 1, wherein the upper memory chip is electrically connected to the connected points on the upper surface of the substrate via golden ball by coating manner.

5. The miniaturized small memory card according to claim 1, wherein the lower memory chip is electrically connected to the connected points of the lower surface of the substrate via golden ball by coating manner.
